(19) United States
(12) Patent Application Publication
(10) Pub. No.: US 2009/0126793 A1
(43) Pub. Date: May 21, 2009

(54) Transparent photovoltaic module

(76) Inventor: Martin William Collins, Staten Island, NY (US)

Correspondence Address: Martin Collins, 162 Catherine St., Staten island, NY, 10302, US

(21) Appl. No.: 11/986,261

(22) Filed: Nov. 20, 2007

(51) Int. Cl. H01L 31/04

(52) U.S. Cl. 136/259

(57) ABSTRACT

A multi-layered transparent photovoltaic cell of the silicon variety. With transparent electrodes on both sides of each of the two independent silicon structures. The spectral makeup of the captured light is influenced by designing/controlling the optical characteristics of the layers of the two photovoltaic layers, and their non-conductive components. Light passing thru the collector that is not captured for photovoltaic purposes is available to provide illumination to the interior of an office, dwelling, or vehicle.

### OTHER REFERENCES

U.S. Pat. No. 4,663,495
U.S. Pat. No. 6,646,196
U.S. Pat. No. 5,221,363
U.S. Pat. No. 6,858,461
U.S. Pat. No. 5,602,457
U.S. Pat. No. 4,332,974
U.S. Pat. No. 5,228,925

### BACKGROUND OF THE INVENTION

The present invention relates generally to the photovoltaic sciences, and more particularly, to the advantages of perceived transparency in photovoltaic cell arrangements. Most research today is focused on two aspects of solar power; increased efficiency, or reduced panel costs. My design is using the latest existing technology, and maximizing collection area.

Most types of photovoltaic cells are commonly constructed using doped silicon, creating N-type and P-type silicon is not new. I am not inventing any new silicon. But, I am suggesting a specific use for “multi-layering” and creating a tuned cell that has a much greater efficiency, and in designing a cell that is transparent I have created a new array of possibilities for the mass deployment of solar cells, especially on a large commercial project.

Photovoltaic cells have previously been completely opaque. And a significant problem has been the ability to locate enough of them to achieve a significant amount of power for a commercial application. Current solar collection panels are bulky, and unattractive. They can quickly overwhelm and dominate a landscape or view.

My solution incorporates photovoltaic cells into the existing components of a building or vehicle. My design can be integrated into a project in such a way that it can make positive contributions economically, environmentally, and aesthetically. There is an inherent amount of inefficiency born into the design, but the sheer numbers of modules that can be deployed, almost invisibly, easily overcomes this. Imagine a downtown high rise with photovoltaic panels instead of traditional glass windows. By combining existing and new technologies, with new design ideas, I have come up with a very unobtrusive design for a solar collector that would not require an architect to make any design concessions.

### SUMMARY OF THE INVENTION

Previously, solar collection efforts have required vast square footages for effective energy collection. They have been unsightly, and tended to dominate the surrounding landscape.

This photovoltaic module containing two layers of photovoltaic cells solves a host of issues. Each cell is tuned by doping to maximize its efficiency within a specific spectral range. The silicon material/collection areas of each have exactly matching patterns of void areas. The voided areas contribute to the perceived transparency of the module. This transparency allows a usable amount of illumination to still enter the room, while supporting the primary function of a solar collector. A reflective shade inside the room can be deployed to block unwanted light from entering the room. This reflected energy, will in turn increase the output of the module.

The modules perform many jobs. Generating a usable electric current thru their photovoltaic function, as well as completing a light filtering task by blocking/capturing solar energy such as infrared or UV. Lastly, the modules perform a structural task by replacing windows. By using the module to replace a conventional window, there is an immediate cost benefit, or at the very least a cost offset. If transparent alumina is utilized during the fabrication of the modules, then even occupant security is increased.

“The prior art, of course, is replete with devices and techniques employed in the production of solar cells. Most photovoltaic modules have been designed with a view toward reduction in initial costs of materials. This, of course, results in penalties in performance, of efficiency as well as production costs. However, as pointed out in U.S. application Ser. No. 918,869, now abandoned, it is possible to fabricate a photovoltaic module which is substantially transparent to substantially all solar energy not used to produce electricity. Because of such transparency, the temperature of the module is substantially minimized with an attendant increase in the overall efficiency of the module. For example, it has been found that where cell temperature has been reduced because of module transparency, an improvement in electrical output has been experienced.”

Quoted from U.S. Pat. No. 4,184,903

### Jan. 22, 1980

### BRIEF DESCRIPTIONS OF THE DRAWINGS

The above and other features can be further and more easily explained and understood by the following drawings. These drawings are not to any particular scale, but do convey the functions, components, and key ideas of the invention.

FIG. 1 is a layered view of a module and its frame.

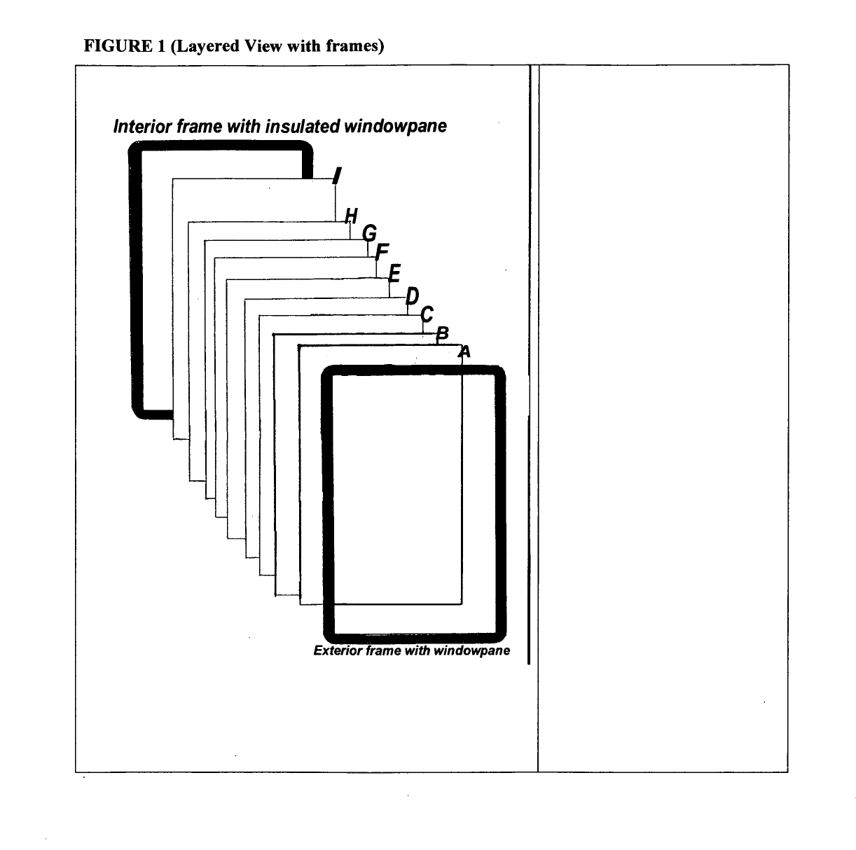

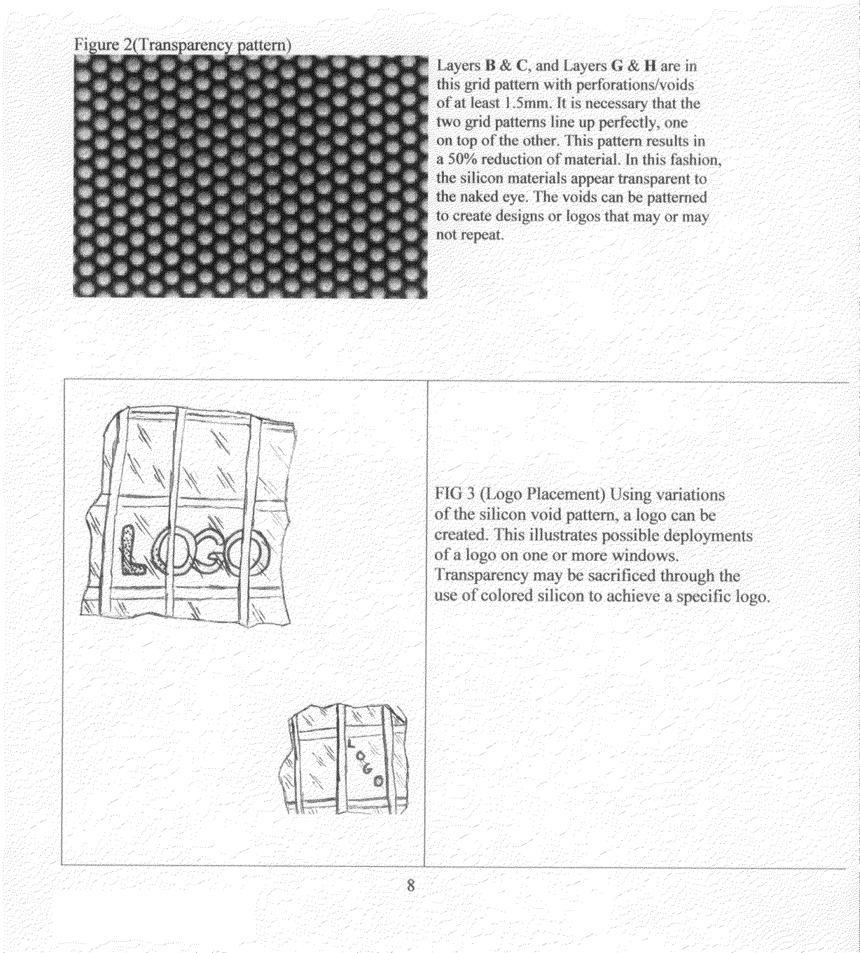

Sunlight enters through “A” side

A conductive, transparent contact grid

B & C transparent silicon that is tuned to maximize efficiency in a specific spectral range. B is n-type silicon, C is p-type silicon

D conductive, transparent contact grid

E non-conductive, transparent separator material

F conductive, transparent contact grid

G & H silicon tuned to maximize efficiency in a specific spectral range. G is n-type silicon, H is p-type silicon

I conductive and transparent contact grid

Layers B & C and G & H have a pattern of 1.5 mm (minimum) voids that create the perception of transparency.

Exterior and Interior frames are attached to interior & exterior windowpanes. Frames are attached to each other with components A through I held firmly in place between the glass panes.

FIG. 2 is an illustration of the “void” pattern that is needed to achieve perceived transparency. The voids need to be at least 50% of the area, with the remaining 50% being occupied by the silicon collection materials.

Layers B & C, and Layers G & H are in this grid pattern with perforations/voids of at least 1.5 mm. It is necessary that the two grid patterns line up perfectly, one on top of the other. This pattern results in 50% reduction of material. In this fashion, the silicon materials appear transparent to the naked eye. The voids can be patterned to create designs or logos that may or may not repeat.

FIG. 3 is an illustration of the possible logo placements.

Using variations of the silicon void pattern, a logo can be created. This illustrates possible deployments of a logo on one or more windows.

Transparency may be sacrificed through the use of colored silicon to achieve a specific logo.

A Photovoltaic Module Containing:

1) a transparent electrode

2) two “tuned” and transparent photovoltaic layers of doped silicon, 1 layer is P-type, and the other layer is N-type

3) a second transparent electrode

4) a separating non-conductive, transparent layer

5) a third transparent electrode

6) two “tuned” photovoltaic layers of doped silicon, tuned to complement the layer in claim 2, again 1 P-type and 1 N-type

7) a fourth transparent electrode

8) all components from claim 1, thru claim 7 are “sandwiched” between window glass. The most interior glass may or may not be insulated single or double pane glass

9) The four layers of doped silicon in claim 2, and claim 6 are identically patterned with voids of at least 1.5 mm.

10) The patterns in claim 9 are corresponding on all layers of silicon. When looking at the panels, the silicon areas will appear to be non-existent. Your eye will naturally look through the panel.

11) There is no maximum size for the voids in claim 9, and they can result in a repeating or non-repeating design or logo(s).

12) The pattern or logo in claim 11 could be limited to one panel, or they might be achieved through a combination of panels.

13) Windowpanes and components in claims 1 through 8 are mounted in a two-part frame that attaches from the front to the back.

14) Attached to the interior window frame, is a Mylar or similarly reflective material shade. This shade may or may not be pulled up and down by an electric motor.

15) The shade in claim 14 may be controlled in a manner that its “default” position is open so as to maximize reflectivity and thus increase the amount of light entering the module.

16) The final dimensions of the module are bound only by the eventual planned function or deployment of the module.

17) All the components will be framed in an aluminum structure typical of the framing requirement for any typical photovoltaic cell.

18) After framing and wiring, the “window” module will be complete. It will be suitable for immediate installation into a pre-built & pre-wired receptor window opening.

19) Modules in claim 18 could be purpose built and also adapted for use as skylights in a structure.

20) The non-conductive separator in claim 4 could be constructed of glass or “optically transparent alumina.”

21) The glass panes in claim 8 may also be constructed from optically transparent alumina.

22) Transparent alumina is a relatively new material that is stronger than steel of the same thickness. This would greatly increase the strength of the panel, and offer the building more resistance to bullets and offer a higher level of blast protection than glass alone. This could be beneficial for high profile buildings, structures, or occupants at an increased risk to sustain violence. This would provide a higher level of protection from certain types of extreme weather damage.
